(19) United States
(12) Patent Application Publication
(10) Pub. No.: US 2025/0300023 A1
(43) Pub. Date: Sep. 25, 2025

(54) METHOD OF MANUFACTURING SEMICONDUCTOR DEVICE, METHOD OF INSPECTING SEMICONDUCTOR DEVICE, AND INSPECTION DEVICE

(71) Applicant: Renesas Electronics Corporation, Tokyo (JP)

(72) Inventors: Naoya KUWAZURU, Tokyo (JP); Manabu YAMAUCHI, Tokyo (JP)

(21) Appl. No.: 19/052,102

(22) Filed: Feb. 12, 2025

(30) Foreign Application Priority Data
Mar. 25, 2024 (JP) 2024-047656

(51) Int. Cl. H01L 21/66

(52) U.S. Cl. CPC H01L 22/14

(57) ABSTRACT

A method of manufacturing a semiconductor device includes preparing a semiconductor device and an inspection device. In the preparing, the semiconductor device has a semiconductor element, a plurality of pads electrically connected to the semiconductor element, and a plurality of bumps arranged on each pad. The inspection device includes a probe card having a plurality of probes, a first holding portion detachably holding the semiconductor device, a cleaning substrate cleaning the probes, and a second holding portion detachably holding the cleaning substrate. The first and second holding portions are movable relatively to the probe card.

### CROSS-REFERENCE TO RELATED APPLICATIONS

The present application claims priority from Japanese Patent Application No. 2024-047656 filed on Mar. 25, 2024, the content of which is hereby incorporated by reference to this application.

### BACKGROUND

The disclosure relates to a method of manufacturing a semiconductor device, a method of inspecting the semiconductor device, and an inspection device.

A semiconductor device, which has a semiconductor element, a plurality of pads, and a plurality of bumps arranged on the plurality of pads, has been known. In a manufacturing method of such a semiconductor device, a plurality of semiconductor devices are formed on a semiconductor substrate, and thereafter electrical characteristics of each semiconductor device are inspected by using a probe card (a so-called on-wafer inspection). At a time of the inspection, each of the plurality of probes included in the probe card contacts with the bump, and the bump adheres to each probe. The bump adhering to each probe may cause electrical connection default at the time of inspecting another semiconductor device of the same semiconductor substrate. Therefore, in the on-wafer inspection of the semiconductor device having the bump, generally, a step of cleaning the plurality of probes is performed in a step of inspecting the plurality of semiconductor devices that are formed on one semiconductor substrate.

There is disclosed a technique listed below. [Patent Document 1] Japanese Unexamined Patent Application Publication No. 2007-294489

As a method of cleaning the probe, there is a method of using an inspection device that has an inspection stage placing the semiconductor substrate, a cleaning stage, and a cleaning sheet attached to the cleaning sheet. An inspection device disclosed in Patent Document 1 is provided so as to cause a cleaning sheet to contact with a tip portion of one probe to cut the tip portion.

### SUMMARY

The general cleaning sheet is comparatively soft, and the probe pressed by and applied to the cleaning sheet subducts with respect to an upper surface of the cleaning sheet. At this time, a frictional force caused by friction between the plurality of probes and the cleaning sheet varies depending on a position of each probe in the probe card. As a result, between the plurality of probes included in the probe card, there arises a problem in which cut amounts of the respective tip portions vary.

Specifically, a subducting amount of the probe, which is positioned at the outermost circumference among the plurality of probes, to the upper surface of the cleaning sheet becomes larger than a subducting amount of the probe, which is positioned at a center among the plurality of probes, to the upper surface of the cleaning sheet. The probe positioned at the center among the plurality of probes is pressed by and applied to the cleaning sheet along with the other probes which are arranged on its circumference. Therefore, the above respective subducting amounts of the probes positioned at the center and at its circumference become comparatively uniformity, and the frictional forces caused by them also becomes comparatively uniformity. In contrast, a subducting amount of the probe, which is positioned at the outermost circumference among the plurality of probs, to the upper surface of the cleaning sheet positioned outside from the outermost circumference becomes larger than the above respective subducting amounts of the probes positioned at the center and on its circumference. As a result, the frictional force caused between the probe, which is positioned at the outermost circumference among the plurality of probes, and the cleaning sheet becomes larger than the frictional force caused between the probe, which is positioned at the center among the plurality of probes, and the cleaning sheet, and the cut amount of the tip portion of the probe positioned at the outermost circumference among the plurality of probes becomes larger than that of the probe positioned at the center among the plurality of probes.

The other problems and the novel features will be apparent from the description of the present specification and the accompanying drawings.

A method of manufacturing a semiconductor device according to the present disclosure includes preparing a semiconductor substrate and an inspection device. In the preparing, the inspection device has a probe card having a plurality of probes, a first holding portion detachably holding the semiconductor substrate, a cleaning substrate cleaning the plurality of probes, and a second holding portion detachably holding the cleaning substrate. The first holding portion and the second holding portion are movable relatively to the probe card. The method of manufacturing the semiconductor device further includes, in the inspection device, cleaning the plurality of probes by using the cleaning substrate held by the second holding portion, inspecting electrical characteristics of a semiconductor element by causing the plurality of probes of the semiconductor substrate held by the first holding portion to contact with the plurality of probes after the cleaning, and processing the semiconductor substrate after the inspecting.

A method of inspecting a semiconductor device according to the present disclosure includes preparing a semiconductor substrate and an inspection device. The inspection device has a probe card having a plurality of probes, a first holding portion detachably holding the semiconductor substrate, a cleaning substrate cleaning the plurality of probes, and a second holding portion detachably holding the cleaning substrate. The first holding portion and the second holding portion are movable relatively to the probe card. The method of inspecting the semiconductor device further includes, in the inspection device, cleaning the plurality of probes by using the cleaning substrate held by the second holding portion, and inspecting electrical characteristics of the semiconductor element by causing a plurality of bumps of the semiconductor substrate held by the first holding portion to contact with the plurality of probes after the cleaning.

An inspection device according to the present disclosure includes a probe card having a plurality of a probes, a holding portion detachably holding a semiconductor substrate, a cleaning substrate cleaning the plurality of probes, and a second holding portion detachably holding the cleaning substrate. The first holding portion and the second holding portion are movable relatively to the probe card. The inspection device is capable of switching a first state in which the plurality of proves contact with the plurality of bumps of the semiconductor substrate held by the first holding portion, and a second state in which the plurality of probes contact with the cleaning substrate held by the second holding portion.

According to the present disclosure, variations of the cut amounts of the tip portions can be suppressed between the plurality of probes included in the probe card.

### BRIEF DESCRIPTION OF THE DRAWINGS

FIG. 1 is a diagram for explaining an inspection device according to an embodiment of the present disclosure, the inspection device being used in a step of inspecting electrical characteristics of a semiconductor element in a manufacturing method of a semiconductor device according to the embodiment of the present disclosure.

FIG. 2 is a plan view of a second holding portion of the inspection device according to the embodiment of the present disclosure.

FIG. 3 is a partially enlarged cross-sectional view for explaining the second holding portion of the inspection device according to the embodiment of the present disclosure.

FIG. 4 is a diagram for explaining a step of cleaning a plurality of probes of the inspection device in the manufacturing method of the semiconductor device according to the embodiment of the present disclosure.

FIG. 5 is a diagram for explaining a state in which a first holding portion and the second holding portion are moved relatively to a probe card, the state being realized after a step of cleaning a plurality of probes of the inspection device and before a step of inspecting the electrical characteristics of the semiconductor element in the manufacturing method of the semiconductor device according to the embodiment of the present disclosure.

FIG. 6 is a diagram for explaining the step of inspecting the electrical characteristics of the semiconductor element in the manufacturing method of the semiconductor device according to the embodiment of the present disclosure.

FIG. 7 is a plan view of a first modification example of the second holding portion of the inspection deice according to the embodiment of the present disclosure.

FIG. 8 is a plan view of a second modification example of the second holding portion of the inspection device according to the embodiment of the present disclosure.

FIG. 9 is a schematic diagram for explaining that in an inspection device of a comparative example, a frictional force caused between the plurality of probes and a cleaning sheet attached to an upper surface of a cleaning stage varies depending on a position of each probe in the probe card.

### DETAILED DESCRIPTION

Hereinafter, embodiments will be explained with reference to the drawings. Note that the same reference numerals are denoted to the same or corresponding components in the following drawings, and a description thereof will not be repeated.

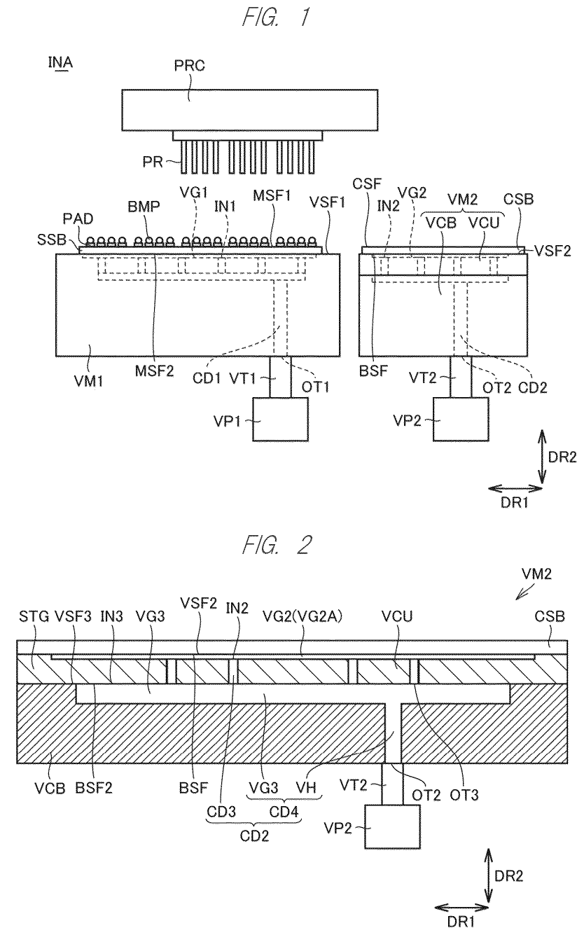

As shown in FIG. 1, an inspection device INA according to an embodiment of the present disclosure is a device for electrical characteristic of a semiconductor element (not shown) included in a semiconductor substrate SSB. The inspection device INA is used in a step of inspecting the electrical characteristics of the semiconductor element included in the semiconductor substrate SSB in a manufacturing method of the semiconductor device.

A semiconductor substrate SSB has, for example, a plurality of semiconductor elements, a plurality of pads PAD, and a plurality of bumps BMP. Each of the plurality pads PAD is electrically connected to each of the plurality of semiconductors elements. The semiconductor substrate SSB has a first principal surface MSF1 in which each of the plurality of pads PAD is mutually arranged side by side, and a second principal surface MSF2 located opposite the first principal surface MSF1. Each of the plurality of bumps BMP are arranged on each of the plurality of pads PAD. Each of the plurality of bumps BMP are, for example, a solder bump. Note that a material forming the bump BMP is not limited to solder, and may be any conducting material. A material forming the bump BMP includes, for example, at least one selected from a group that is formed by Lin (Sn), Nickel (Ni), Silver (Ag), Cupper (Cu), and Aurum (Au).

Note that the semiconductor substrate SSB may further have a not-shown configuration such as a protective film.

### <Configuration of Inspection Device>

A configuration of the inspection device INA will be explained with reference to FIGS. 1 to 3. As shown in FIG. 1, the inspection device INA mainly includes a probe card PRC, a first holing portion VM1, a second holing portion VM2, and a cleaning substrate CSB.

In the present specification, the cleaning substrate CSB means a harder member than a general cleaning sheet that is made of a resin (for example, a silicone resin) containing abrasive grain (for example, oxide aluminum). Hardness of the material forming the cleaning substrate CSB is higher than hardness of the resin material mainly forming the above cleaning sheet. The cleaning substrate CSB has a cleaning surface CSF, and a back surface BSF located opposite the cleaning surface CSF. Hardness of the cleaning surface CSF is higher than hardness of an abrasive surface of the above cleaning sheet.

The probe card PRC has a plurality of probes PR. In the inspection device INA, the probe card PRC is detachably held by, for example, a not-shown holding portion. The probe card PRC can be arbitrarily selected from a plurality of kinds of probe cards PRC, for example, depending on a substrate device or the like as an inspection object. Namely, in the embodiment of the present disclosure, the kinds of probe PR and probe card PRC that are cleaning objects are not limited particularly.

Each of the plurality of probes extends, for example, parallel to each other. Each of the plurality of probes PR is spaced from each other, for example, in at least one direction orthogonal to an extension direction of each of the plurality of probes. Each of the plurality of probes PR may be spaced from each other in each of two directions that are orthogonal to each extension direction of the plurality of probes PR and orthogonal to each other. Each of the plurality of probes PR, for example, extends along a second direction DR2 orthogonal to a second placement surface VSF2 later described and is spaced from each other in a first direction DR1 along the second placement surface VSF2.

The first holding portion VM1 detachably holds the semiconductor substrate SSB. The first holding portion VM1 has a first placement surface VSF1 on which the second principal surface MSF2 of the semiconductor substrate SSB is placed. The first holding portion VM1 further has, for example, a first trench portion VSG1, a plurality of first inlets IN1, a first outlet OT1, and a first inlet path CD1 connected between the plurality of first inlets IN1 and the first outlet OT1. The first trench portion VSG1 is recessed with respect to the first placement surface VSF1. The plurality of first inlets IN1 is opened in the first trench portion VSG1. The first outlet OT1 is connected to a first pump VP1 via a first outlet pipe. Consequently, during driving the first pump VP1, the second principal surface MSF2 of the semiconductor substrate SSB placed on the first placement surface VSF1 is absorbed by the first placement surface VSF1.

The second holding portion VM2 detachably holds the cleaning substrate CSB. The second holding portion VM2 has the second placement surface VSF2 on which a back surface BSF of the cleaning substrate CSB is placed. The second holding portion VM2 further has, for example, a second trench portion VSG2, a plurality of second inlets IN2, a second outlet OT2, and a second inlet path CD2 connected between the plurality of second inlets IN2 and the second outlet OT2. The second trench portion VSG2 is recessed with respect to the second placement surface VSF2. The plurality of second inlets IN2 are opened in the second trench portion VSG2. The second outlet OT2 is connected to a second pump VP2 via a second outlet pipe VT2. Consequently, during driving the second pump VP2, the back surface BSF of the cleaning substrate CSB placed on the second placement surface VSF2 is absorbed in the second placement surface VSF2. Preferably, the cleaning substrate CSB is provided so as to overlap with the entire second trench portion VG2.

Hardness of the second placement surface VSF2 of the second holding portion VM2 is equal to or higher than hardness of the cleaning surface CSF of the cleaning substrate CSB. The hardness of the second placement surface VSF2 of the second holding portion VM2 is equal to, for example, the hardness of the first placement surface VSF1 of the first holding portion VM1.

The second holding portion VM2 is arranged side by side with the first holding portion VM1 in a first direction DR1 along the second placement surface VSF2. The first direction DR1 is, for example, along a horizontal direction. The second placement surface VSF2 is, for example, parallel to the first placement surface VSF1.

The first holding portion VM1 and the second holding portion VM2 are movable relatively to the probe card PRC. The inspection device INA includes at least one of a first drive portion, which integrally moves the first holding portion VM1 and the second holding portion VM2 with respect to the probe card PRC, and a second drive portion, which moves the probe card with respect to the first holding portion VM1 and the second holding portion VM2. The inspection device INA has, for example, only the first drive portion.

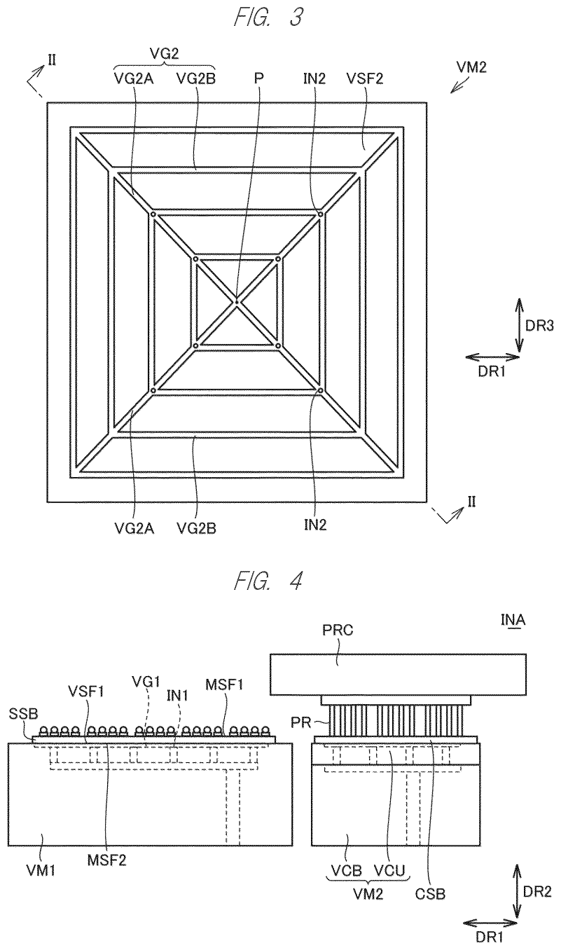

A specific example of the second holding portion VM2 will be explained with reference to FIGS. 2 and 3.

As shown in FIG. 2, the second holding portion VM2 has a base VCB and an absorption unit VCU.

The absorption unit VCU has the second placement surface VSF2, and the back surface BSF2 located opposite the second placement surface VSF2. The absorption unit VCU further has a plurality of second inlets IN2, a plurality of third outlets OT3 opened in the back surface BSF2, a plurality of third outlet paths CD3 connected between each of the plurality of second inlets IN2 and each of the plurality of third outlets OT3. Each of the plurality of third inlet paths CD3 extends, for example, along a second direction DR2. Each of the plurality of third inlet paths CD3 is formed, for example, in a through-hole passing through the absorption unit VCU2 in the second direction DR2. Note that each third inlet path CD3 may extend along a direction orthogonal to the second direction DR2. A part of each third inlet path CD3 may extend along the first direction DR1.

A bottom surface of the second trench portion VG2 extends along the first direction DR1. The bottom surface of the second trench portion VSG2 extends, for example, parallel to the first direction DR1. An opening diameter of each of the plurality of second inlets IN2 is equal or smaller than a diametrical distance (hereinafter, described as a width of the second trench portion VG2) of an inner circumference surface of the second trench portion VG2 opposing to a direction orthogonal to the extension direction of the second trench portion VG2.

A material forming the absorption unit VCU is, for example, a metal material. The material forming the absorption unit VCU is, for example, the same material as a material forming the first holding portion VM1.

The base VCB has a third placement surface VSF3, at least one third inlet IN3, a second outlet OT2, and at least one fourth inlet path CD4 connected between the at least one third inlet IN3 and the second outlet OT2. The third placement surface VSF3 is a surface on which a back surface BSF2 of the absorption unit VCU is placed. The at least one third inlet IN3 is arranged so as to overlap with each of the plurality of third outlets OT3 of the absorption unit VCU. Consequently, the at least one fourth inlet path CD4 communicates with each of the plurality of third inlet path CD3 included in the absorption unit VCU.

The base VCB further has, for example, a third trench portion VG3 recessing with respect to the third placement surface VSF3. The third trench portion VG3 faces each of the plurality of third outlets OT3 as well as faces a part of the back surface BSF2 of the absorption unit VCU. An opening end of the third trench portion VG3 of the third placement surface VSF3 forms the third inlet IN3. The at least one fourth inlet path CD4 is configured by, for example, the third trench portion VG3, and a hole portion VH that has one end opened in the bottom surface of the trench portion VG3 and the other end continuous with the second outlet OT2. The third placement surface VSF3 of the base VCB acts as an absorption surface, which absorbs the back surface BSF of the absorption unit VCU, during driving the second pump VP2 (see FIG. 1).

From the different standpoint, the second inlet path CD2 is connected between the plurality of second inlets IN2 and the second outlet OT2, and has a convergence portion at which air absorbed from the plurality of second inlets IN2 converges. In the second holding portion VM2 shown in FIGS. 1 and 2, the convergence portion is confirmed as the third trench portion VG3.

Hardness of the third placement surface VSF3 of the base VCB is equal to or larger than hardness of the cleaning surface CSF of the cleaning substrate CSB. The material forming the base VCB is, for example, a metal material. The material forming the base VCB is the same as, for example, the material forming the first holding portion VM1.

As shown in FIG. 3, the second trench portion VG2 has a plurality of first trench parts VG2A and a plurality of second trench parts VG2B. In a plan view, each of the plurality of first trench parts VG2 extends along a radius direction with respect to a reference point P of the second placement surface VSF2, and is spaced from each other in a circumferential direction with respect to the reference point P.

In the plan view, each of the plurality of second trench parts VG2B is annularly provided around the reference point P, and intersects with each of the plurality of first trench parts VG2A. Preferably, in the second trench portion VG2, each of the plurality of inlets IN2 is opened in at least one intersection region among a plurality of intersection regions in which each of the plurality of first trench parts VG2A and each of the plurality of second trench parts VGB2 intersect with each other. As shown in FIG. 3, each of the plurality of second inlets IN2 is opened, for example, only in a part of the intersection region among the plurality of intersection regions.

Note that each of the plurality of second inlets IN2 may be opened in a region, which extends between the two adjacent intersection regions as described above, in the second trench portion VG2.

In the plan view, each of the plurality of first trench parts VG2A is, for example, orthogonal to each other. In the plan view, each of the plurality of second trench parts VG2B extends, for example, linearly. In the plan view, each of the plurality of second trench parts VG2B is, for example, continuous to each other on an angular annular state. The extension direction of a part of the second trench part VG2B among the plurality of second trench parts VG2B is, for example, orthogonal to the extension direction of the other part of the second trench part VG2B among the plurality of second trench parts VG2B.

Each width of the plurality of second trench portions VG2 is, for example, constant. Each width of the plurality of first trench parts VG2A is, for example, equal to each other. Each width of the plurality of first trench parts VG2A is, for example, equal to each width of the plurality of second trench parts VG2B.

A distance in the second direction DR2 between the second placement surface VSF2 and the bottom surface of the second trench portion VG2 (hereinafter, described as depth of the second trench portion VB2) is, for example, constant. Each depth of the plurality of first trench parts VG2A is, for example, equal to each other. Each depth of the plurality of first trench parts VG2A is, for example, equal to each depth of the plurality of second trench parts VG2B.

### <Manufacturing Method of Semiconductor Device>

A manufacturing method of a semiconductor device according to an embodiment of the present disclosure will be explained with reference to FIGS. 1 and 4 to 6. Note that illustrations of the first pump VP1 and the like will be omitted in FIGS. 4 to 6.

In the manufacturing method of the semiconductor device, the semiconductor substrate SSB and the inspection device INA that are shown in FIG. 1 are firstly prepared. In the semiconductor substrate SSB prepared in this step, the semiconductor element, the plurality of pads PAD, and the plurality of bumps BMP are formed. For example, in this step, the semiconductor substate SSB is carried on and absorbed in the first placement surface VSF1 of the first holding portion VM1 of the inspection device INA. In this step, the cleaning substrate CSB is held by the second holding portion VM2. In this step, the probe card PRC has only to be arranged at such as a position not to hinder the carriage of the semiconductor substate SSB with respect to the first holding portion VM1.

Secondly, as shown in FIG. 4 after the above first step, the plurality of probes PR are cleaned by using the cleaning substrate CSB held by the second holding portion VM2. In this step, at the beginning, each of the plurality of probes PR is arranged in the second direction DR2 and at a position overlapping with the cleaning surface CSF of the cleaning substrate CSB. Next, a state in which each tip portion of the plurality of probes PR contacts with the cleaning surface CSF (second state) is realized. Next, one of the probe card PRC and the second holding portion VM2 moves in a direction along the cleaning surface CSF with respect to the other, and the motion makes one of each tip portion of the plurality of probes PR and the cleaning surface CSF to be slid with respect to the other. Consequently, foreign matters adhering to each tip portion of the plurality of probes PR are removed, and each tip portion of the plurality of probes PR is cleaned. After completion of this step, the probe card PRC moves relatively to the second holding portion VM2, and each tip portion of the plurality of probes PR is such as a state not to contact with the cleaning surface CSF.

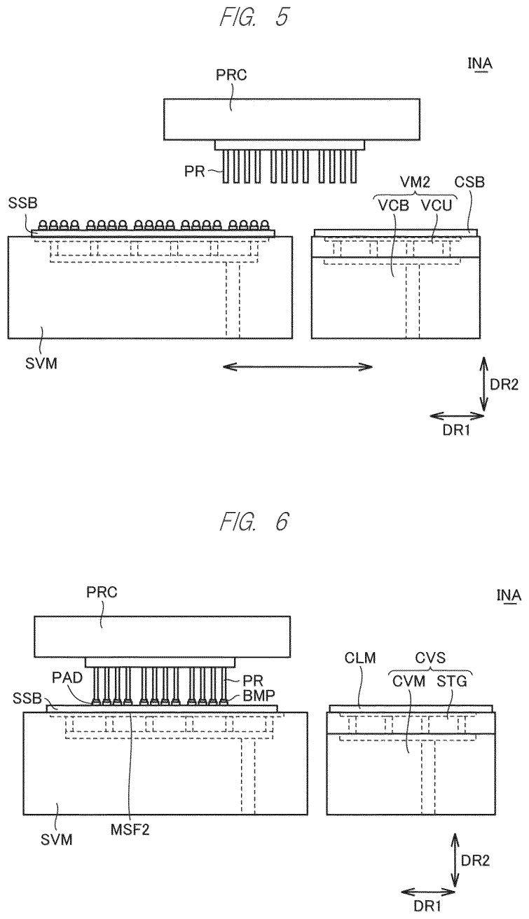

Thirdly, after the above second step, as shown in FIG. 6 through a moving step shown in FIG. 5, the electrical characteristics of the semiconductor element included in the semiconductor substrate SSB is inspected. By the moving step shown in FIG. 5, each of the plurality of probes PR is arranged in the second direction DR2 and at such as a position to overlap with each of the plurality of bumps BMP of the semiconductor substrate SSB held by the first holding portion VM1. Next, a state in which each tip portion of the plurality of probes PR contacts with the plurality of bumps BMP (first state) is realized. Each of the plurality of probes PR deforms each of the plurality of bumps BMP. Each of the plurality of probes PR is electrically connected to the semiconductor element via each of the plurality of bumps BMP and the plurality of pads PAD. Next, the electrical characteristics of the semiconductor element is inspected by using the plurality of probs PR.

When one semiconductor substrate SSB has the plurality of semiconductor elements, this step is performed with respect to all the semiconductor elements to be inspected in the one semiconductor substrate SSB. After completion of this step, the semiconductor substrate SSB is carried out of the inspection device INA. After the completion of this step, the cleaning substrate CSB may be carried out of the inspection device INA or be continuously held by the second holding portion VM2.

Fourthly, after the above third step, any processing is performed with respect to the semiconductor substrate SSB. In this step, any processing may be performed based on an inspection result of the above third step. In this step, the semiconductor substrate SSB may be diced, and each of the plurality of semiconductor elements may be individuated.

By the manufacturing method of the semiconductor device as described above, the semiconductor device can be manufactured from the semiconductor element included in the semiconductor substrate SSB.

### <Inspecting Method of Semiconductor Device>

An inspecting method of a semiconductor device according to the present disclosure includes the first to third steps of the manufacturing method of the semiconductor device as described above. By such an inspecting method of the semiconductor device, the electrical characteristics of the semiconductor element include in the semiconductor substrate SSB can be inspected.

### <Effects>

Effects of the inspection device INA and the manufacturing method of the semiconductor device, which uses the inspection device INA, will be explained based on a comparison with a comparative example shown in FIG. 9. In FIG. 9, in a comparative-example inspection device that includes a probe card, an inspection stage placing a semiconductor substrate, a cleaning stage, and a cleaning sheet attached to the cleaning stage, a plurality of probs of the probe card PRC are pressed by and applied to the cleaning sheet CST. As described above, the general cleaning sheet CST is made of a resin (for example, a silicone resin) including abrasive grain (for example, oxide aluminum). Therefore, when the plurality of probes are pressed by and applied to the cleaning sheet CST, a region pressed by and applied to the plurality of probes in the cleaning sheet CST is subducted further than the other region. At this time, the probe PR1 positioned at a center of the plurality of probes is pressed by and applied to the cleaning sheet CST together with the other plurality of probes which are arranged adjacent to a circumference of the probe PR1. In the cleaning sheet CST, the region pressed by and applied to the probe PR1 (hereinafter, described as a first region) is subdued together with a circumference region of the first region, that is, a region pressed by and applied to the other plurality of probes adjacent to the probe PR1 (hereinafter, a first circumference region). In the other hand, in the cleaning sheet CST, a region pressed by and applied to the probe PR2 positioned on the outermost circumference among the plurality of probes (hereinafter, described as a second region) is adjacent to such as a region not to be pressed by and applied to the probe (hereinafter, described as a second circumferential region). Consequently, in the cleaning sheet CST, a subducting amount of the above second region to the above second circumference region becomes larger than a subducting amount of the first region to the first circumference region. By this, a frictional force caused between the probe PR2 and the above second region of the cleaning sheet CST becomes larger than a frictional force caused between the probe PR1 and the above first region of the cleaning sheet CST. A cut amount of a tip portion of the probe PR2 become larger than a cut amount of a tip portion of the probe PR1. Therefore, in the comparative-example inspection device, there is a problem in which lifetime of the probe card is short. In the manufacturing method of the semiconductor device, which uses the comparative-example inspection device, there is a problem in which contact failure between the probe PR2 and the bump is easily caused.

As a means for solving those problems, use of the cleaning substrate CSB as a cleaning member is raised instead of the cleaning sheet CST. The cleaning substrate CSB needs to be certainly held in the inspection device in order to properly clean the plurality of probes during a cleaning step. In the other hand, the cleaning substrate CSB needs to be easily detached from the inspection device in order to removes foreign matters moved from the probe during a maintenance. The cleaning stage of the comparative-example inspection device has no structure for detachably holding the cleaning substrate CSB. Use of the cleaning substrate CSB in the comparative-example inspection device makes it necessary to hold the cleaning substrate CSB at the inspection stage. In this using method, it becomes necessary to have, between a step of using the cleaning substrate CSB to clean the plurality of probes and a step of inspecting the electrical characteristics of the semiconductor element, a step of carrying one of the cleaning substrate CSB and the semiconductor substrate out of the inspection stage and a step of carrying the other of the cleaning substrate CSB and the semiconductor substrate in the inspection stage. As a result, throughputs of the manufacturing method and the inspecting method of the semiconductor device that use the cleaning substrate CSB in the comparative-example inspection device considerably decrease in comparison with throughputs of the manufacturing method and the inspecting method of the semiconductor device that use the cleaning sheet CST in the comparative-example inspection device.

In contrast, the inspection device INA includes the first holding portion VM1 for detachably holding the semiconductor substrate SSB, and the second holding portion VM2 for detachably holding the cleaning substrate CSB. This makes it possible to use the cleaning substrate CSB, which is held by the second holding portion VM2, to clean the plurality of probes PR in the manufacturing method of the semiconductor device using the inspection device INA. For this reason, in the inspection device INA, variations of the above cut amounts between the plurality of probes PR can be suppressed in a comparison with a case of using the cleaning sheet CST as a cleaning member in the above comparative example. As a result, the lifetime of the probe card PRC of the inspection device INA becomes longer than that of a case of using the cleaning sheet CST in the above comparative-example inspection device. Further in the manufacturing method and the inspecting method of the semiconductor device that use the inspection device INA, a step of carrying in and out of each of the cleaning substrate CSB and the semiconductor substrate between the above second step and the above third step is unnecessary. As a result, the throughputs of the manufacturing method and the inspecting method of the semiconductor device that use the inspection device INA are considerably improved in the comparison with the throughputs of the manufacturing method and the inspecting method of the semiconductor device that use the cleaning substrate CSB in the above comparative-example inspection device. Also, according to the manufacturing method and the inspecting method of the semiconductor device that use the inspection device INA, the electrical characteristics of the semiconductor element by the probe PR in which the foreign matters have been removed are inspected, so that the occurrence of the inspection faults caused by the foreign matters can be suppressed.

In the above inspection device INA, the second holding portion VM2 has the second placement surface VSF2 placing the cleaning substrate CSB, the second trench portion VG2 subducted with respect to the second placement surface VSF2, and the second inlet path CD2 having the plurality of second inlets IN2 that is opened in the second trench portion VG2. Such a second holding portion VM2 is capable of vacuum-absorbing the cleaning substrate CSB. That is, the second holding portion VM2 can easily switch an ON state in which a holding force necessary for properly cleaning the plurality of probes is operated between the cleaning substrate CSB and the second holding portion and an OFF state in which the holding force is not operated between the cleaning substrate CSB and the second holding portion.

In the above inspection device INA, the second trench portion VG2 has the plurality of first trench parts VG2A and the plurality of second trench parts VG2B that communicate with one another. In the plan view, each of the plurality of first trench parts VG2A extends along the radius direction with respect to the reference point P of the second placement surface VSF2 and is spaced from each other in the circumferential direction with respect to the reference point P. In the plan view, each of the plurality of second trench parts VG2B is provided annually around the reference point P, and intersects with each of the plurality of first trench parts VG2A. The second inlet path CD2 is opened in a region in which each of plurality of first trench parts VG2A and each of plurality of second trench parts VG2B intersect with each other in the second trench portion VG2. By doing so, since the cleaning substrate CSB is placed on the second placement surface VSF2 so as to overlap with the entire second trench portion VG2, the competent holding force is operated between the second placement surface VSF2 and the back surface BSF of the cleaning substrate CSB.

In the above inspection device INA, the second inlet path CD2 has a joining portion at which air absorbed from the plurality of inlets IN2 is joined. The second holding portion VM2 has a third trench portion VG3 operated as the joining portion. This makes it possible to connect the plurality of second inlets IN2 to the one second outlet OT2.

In the above inspection device INA, the material forming the cleaning substrate CSB is harder than the material forming the plurality of bumps BMP of the semiconductor substrate SSB. Therefore, the foreign matters caused by the bump BMP adhered to the probe PR can be easily removed by the cleaning step of using the cleaning substrate CSB.

In the above inspection device INA, the first holding portion VM1 and the second holding portion VM2 are movable relatively to the probe card PRC, as well as are arranged side by side in the first direction DR1 intersecting with the extension direction of each of the plurality of probes PR. Doing so makes it possible to smoothly switch the above second step and the above third step in the manufacturing method and the inspection method of the semiconductor device that use the inspection device.

In the manufacturing method and the inspection method of the semiconductor device that use the above inspection device INA, after each of the plurality of probes PR presses and deforms each of the plurality of bumps BMP in the third step of inspecting the electrical characteristics of the semiconductor element, the electrical characteristics of the semiconductor element are inspected via the plurality of bumps BMP. In such an inspecting step, the foreign matters caused by the bump BMP easily adhere to each of the plurality of probes PR. That is, the manufacturing method and the inspection method of the semiconductor device that use the semiconductor substrate SSB having the bump BMP has a tendency for the foreign matters to easily adhere to each of the plurality of probes PR and for frequency of the cleaning step with respect to the probe PR to increase in comparison with the manufacturing method and the inspecting method of the semiconductor device that use the semiconductor substrate SSB having no bump BMP. According to the manufacturing method and the inspecting method of the semiconductor device according to the present embodiment, use of the inspection device INA makes it possible to remove the foreign matters without decreasing the throughputs as described above. Therefore, the inspection device INA is particularly proper to the manufacturing method and the inspection method of the semiconductor device that use the semiconductor substrate SSB having the bump BMP.

In the above inspection device INA, the second holding portion VM2 includes the base VCB and the absorption unit VCU. The absorption unit VCU has the second placement surface VSF2, the second trench portion VG2, the plurality of inlets IN2, and a third inlet path CD3 that is one part of the second inlet path CD2. The base VCB has at least one outlet OT2 and a fourth inlet path CD4 that is the remining portion of the second inlet path CD2. The third trench portion VG3 included in the fourth inlet path CD4 is continuous to the third inlet path CD3, as well as faces the back surface VSF2 of the absorption unit VCU. In such a second holding portion VM2, during driving the second pump VP2, the second placement surface VSF2 can operate as an absorption surface for absorbing the cleaning substrate CSB, as well as the third placement surface VSF3 in which the third trench portion VG3 is opened can operate as an absorption surface for absorbing the absorption unit VCU.

### <Modification Examples of Inspection Device, Manufacturing Method of Semiconductor Device, and Inspecting Method>

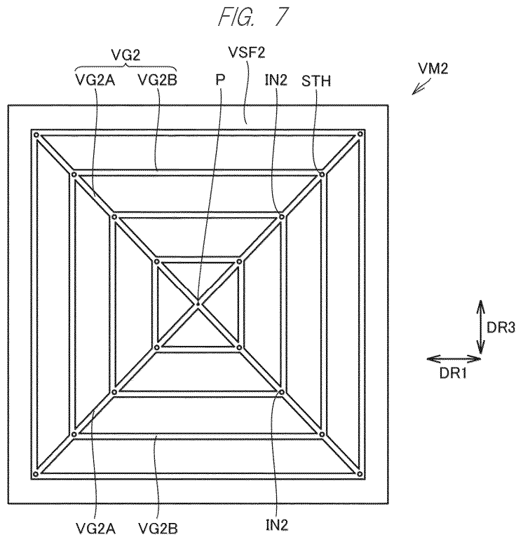

As shown in FIG. 7, in the second trench portion VG2, each of the plurality of second inlets IN2 may be opened in all of intersection regions in which each of the plurality of first trench parts VG2A and each of the plurality of second trench parts VG2B intersect with one another. The second inlet IN2 may be opened in an intersecting region with which the plurality of first trench parts VG2A intersect at the reference point P.

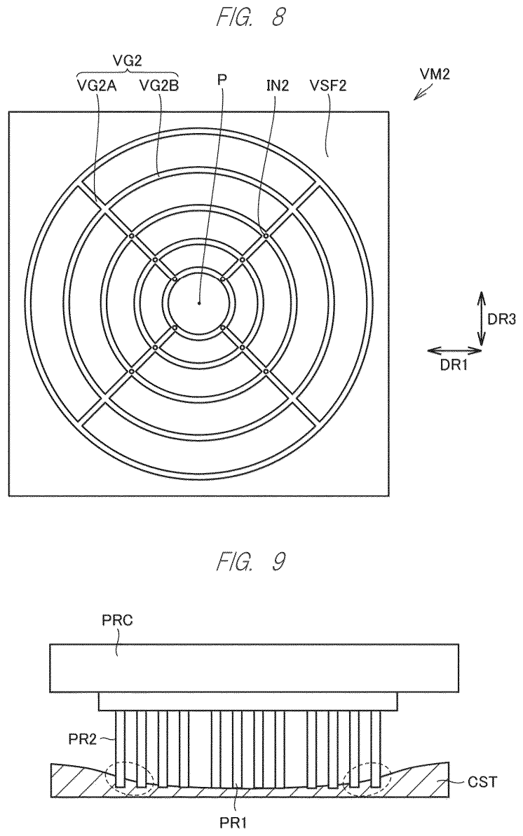

A planar shape of the second trench portion VG2 is not limited particularly. As shown in FIGS. 3 and 7, the plurality of second trench parts VG2B may extend linearly and, as shown in FIG. 8, may extend circumferentially about the reference point P of the second placement surface VSF2. Even in both cases, the competent holding force can be operated between the second placement surface VSF2 and the back surface BSF of the cleaning substrate CSB. Note that the reference point P of the second placement surface VSF2 may be any point on the second placement surface VSF2, for example, be a center of the second placement surface VSF2 in the plan view.

The number and layout of the plurality of second inlets IN2 are not limited particularly, either. The number and layout of the outlet OT3 of the absorption unit VCU are not limited particularly, either. The absorption unit has only to have at least one outlet OT3. The absorption unit VCU may have the above joining portion.

When the semiconductor substrate SSB has a first semiconductor element and a second semiconductor element, the above third step may have a middle cleaning step of cleaning the plurality of probes PR by using the cleaning substrate CSB held by the second holding portion VM2 between a first inspecting step of inspecting the electrical characteristics of the first semiconductor element and a second inspecting step of inspecting the electrical characteristics of the second semiconductor element. The middle cleaning step can be performed similarly to the above second step shown in FIG. 4. According to the manufacturing method of the semiconductor device which has the middle cleaning step, it is not required to carry each of the semiconductor substrate SSB and the cleaning substrate CSB in and out of the inspection device INA after the above second step until the completion of the above third step. As a result, a decrease in the throughput of the above third step can be suppressed.

Particularly, in the manufacturing method and the inspecting method of the semiconductor device that use the semiconductor substrate SSB having the bump BMP, before the inspection of all the semiconductor elements included in one semiconductor substrate SSB is completed, the foreign matters adhering to each of the plurality of probes PR must normally be removed. In the manufacturing method and the inspecting method of the semiconductor device that use the inspection device INA, even if the middle cleaning step is performed two or most times in the above third step, the decrease in the throughput can be suppressed.

In the above manufacturing method and inspecting method of the semiconductor device, the above second step is performed after the above first step and before the above third step, but is not limited to this. The above second step may be performed after the above third step. By doing so, the foreign matters adhering to the plurality of probes PR in the above third step can be removed without taking time. Further, in the manufacturing method and the inspecting method of the semiconductor device, the above second step may be performed after the above first step and before the above third step, as well as may be performed again after the above third step.

The present disclosure is proper to not the semiconductor device having the bump BMP but the semiconductor device having no bump. In the on-wafer inspection to the semiconductor substrate having no bump, the plurality of probes contact with the bump. At this time, the metal material forming the pad adheres, as foreign matters, to the probe. The present disclosure is also proper to not the foreign matters caused by the bump but the manufacturing method and the inspecting method having the cleaning step for removing the foreign matters caused by the pad and but the inspection device used in the cleaning step.

As described above, the invention made by the present inventors has been specifically explained based on the embodiments, but the present invention is not limited to the above embodiments and, needless to say, can be variously modified within a range of not departing from the scope thereof.

What is claimed is:

1. A method of manufacturing a semiconductor device,
the method comprising preparing a semiconductor substrate and an inspection device,
wherein, in the preparing,
the semiconductor substrate has a semiconductor element, a plurality of pads electrically connected to the semiconductor element, and a plurality of bumps arranged on each of the plurality of pads, and
the inspection device has a probe card having a plurality of probes, a first holding portion detachably holding the semiconductor substrate, a cleaning substrate cleaning the plurality of probes, and a second holding portion detachably holding the cleaning substrate, the first holding portion and the second holding portion being movable relatively to the probe card, and
wherein, in the inspection device,
the method comprising:
cleaning the plurality of probes by using the cleaning substrate held by the second holding portion;
after the cleaning, inspecting electrical characteristics of the semiconductor element by causing the plurality of bumps of the semiconductor device held by the first holding portion to contact with the plurality of probes; and
after the inspecting, processing the semiconductor substrate.

2. The method of manufacturing a semiconductor device according to claim 1,
wherein the second holding portion has a placement surface placing the cleaning substrate, a trench portion subducted with respect to the placement surface, a plurality of inlets opened in the trench portion, at least one outlet opened outside the trench portion, and an inlet path connected between the plurality of inlets and the at least outlet, and
wherein in the cleaning of the plurality of probes, the cleaning substrate is vacuum-absorbed in the second holding portion.

3. The method of manufacturing a semiconductor device according to claim 2,
wherein the trench portion has a plurality of first trench parts and a plurality of trench parts that communicate with one another,
wherein in a plan view, each of the plurality of first trench parts extends along a radius direction with respect to a reference point of the placement surface, and is spaced from each other in a circumferential direction with respect to the reference point,
wherein in the plan view, each of the plurality of second trench parts is provided annually around the reference point, and intersects with each of the plurality of first trench parts,
wherein the inlet path is opened, in the trench portion, in a region in which each of the plurality of first trench parts and each of the plurality of second trench parts intersect with each other, and
wherein in the cleaning of the plurality of probes, the cleaning substrate is arranged so as to overlap with the entirety of the plurality of first trench parts and the entirety of the plurality of second trench parts.

4. The method of manufacturing a semiconductor device according to claim 3,
wherein in the plan view, each of the plurality of second trench parts extends linearly.

5. The method of manufacturing a semiconductor device according to claim 3,
wherein in the plan view, each of the plurality of second trench parts extends circumferentially about the reference point.

6. The method of manufacturing a semiconductor device according to claim 3,
wherein the inlet path is connected between the plurality of inlets and the at least one outlet, and has a joining portion at which air absorbed from the plurality of inlets is joined.

7. The method of manufacturing a semiconductor device according to claim 1,
wherein a material forming the cleaning substrate is harder than a material forming the plurality of bumps.

8. The method of manufacturing a semiconductor device according to claim 1,
wherein the first holding portion and the second holding portion are arranged side by side in a direction intersecting with an extension direction of each of the plurality of probes.

9. The method of manufacturing a semiconductor device according to claim 1,
wherein in the preparing, the semiconductor substrate has a plurality of semiconductor elements, and the plurality of semiconductor elements have a first semiconductor element and a second semiconductor element, and
wherein inspecting the electrical characteristics of the semiconductor element includes:
first inspection of inspecting electrical characteristics of the first semiconductor element;
second inspection of inspecting electrical characteristics of the second semiconductor element by using the cleaning substrate held by the second holding portion, and
middle inspection of inspecting the plurality of probes between the first inspection and the second inspection.

10. The method of manufacturing a semiconductor device according to claim 1,
wherein in the inspecting of the electrical characteristics of the semiconductor element, each of the plurality of probes presses and deforms each of plurality of bumps, and then the electrical characteristics of the semiconductor element are inspected via the plurality of bumps.

11. A method of inspecting a semiconductor element included in a semiconductor substrate,
the method comprising preparing the semiconductor substrate and an inspection device, the semiconductor substrate having a plurality of pads that are electrically connected to the semiconductor element and a plurality of bumps that are arranged on each of the plurality of pads,
wherein the inspection device includes a probe card having a plurality of probes, a first holding portion detachable holding the semiconductor substrate, a cleaning substrate cleaning the plurality of probes, and a second holding portion detachably holding the cleaning substrate, the first holding portion and the second holding portion being movable relatively to the probe card, and
wherein in the inspection device, the method including:
cleaning the plurality of probes by using the cleaning substrate held by the second holding portion; and
after the cleaning, inspecting electrical characteristics of the semiconductor element by causing the plurality of bumps of the semiconductor substrate held by the first holding portion to contact with the plurality of probes.

12. The method of inspecting a semiconductor element according to claim 11,
wherein in the preparing, the semiconductor substrate has a plurality of semiconductor elements, and the plurality of semiconductor elements have a first semiconductor element and a second semiconductor element, and
wherein inspecting the electrical characteristics of the semiconductor element includes:
first inspection of inspecting electrical characteristics of the first semiconductor element;
second inspection of inspecting electrical characteristics of the second semiconductor element; and
between the first inspection and the second inspection, middle cleaning of cleaning the plurality of probes by using the cleaning substrate held by the second holding portion.

13. An inspection device inspecting electrical characteristics of a semiconductor element, the inspection device comprising:
a probe card having a plurality of probes;
a first holding portion detachably holding a semiconductor substrate, the semiconductor substrate having the semiconductor element, a plurality of pads electrically connected to the semiconductor element, and a plurality of bumps arranged on each of the plurality of pads;
a cleaning substrate cleaning the plurality of probes; and
a second holding portion detachably holding the cleaning substrate,
wherein the first holding portion and the second holding portion are movable relatively to the probe card, and
wherein a first state in which the plurality of probes contact with the plurality of bumps of the semiconductor substrate held by the first holding portion and a second state in which the plurality of probes contact with the cleaning substrate held by the second holding portion are switchable.

14. The inspection device according to claim 13,
wherein the second holding portion has a placement surface placing the cleaning substrate, a trench portion subducted with respect to the placement surface, a plurality of inlets opened in the trench portion, at least one outlet opened outside the trench portion, and an inlet path connected between the plurality of inlets and the at least one outlet.

15. The inspection device according to claim 14,
wherein the trench portion has a plurality of first trench parts and a plurality of second trench parts that communicate with one another,
wherein in a plan view, each of the plurality of first trench parts extends along a radius direction with respect to a reference point of the placement surface and is spaced from each other in a circumferential direction with respect to the reference point,
wherein in the plan view, each of the plurality of second trench parts is provided annually around the reference point and intersects with each of the plurality of first trench parts, and
wherein the inlet path is opened in a region, in which each of the plurality of first trench parts and each of the plurality of second trench parts intersect with each other, in the trench portion.

16. The inspection device according to claim 15,
wherein in the plan view, each of the plurality of second trench parts extend linearly.

17. The inspection device according to claim 15,
wherein in the plan view, each of the plurality of second trench parts extends circumferentially about the reference point.

18. The inspection device according to claim 15,
wherein the inlet path is connected between the plurality of inlets and the at least one outlet, and has a joining portion with which air absorbed from the plurality of inlets joins.

19. The inspection device according to claim 14,
wherein the second holding portion includes: an absorption unit having the placement surface, the trench portion, the plurality of inlets, one part of the inlet path;
and a base having the at least one outlet and the other part of the inlet path, and
wherein the other part of the inlet path is continuous to one part the inlet path, and faces a surface other than the placement surface in the absorption.

20. The inspection device according to claim 13,
wherein a material forming the cleaning substrate is harder than a material forming the plurality of bumps, and
wherein the cleaning substrate has a surface on which sandblasting process is performed.
